(19) United States
(12) Patent Application Publication
(10) Pub. No.: US 2024/0203684 A1
(43) Pub. Date: Jun. 20, 2024

(54) METHOD FOR ANALYZING DISTURBING INFLUENCES IN A MULTI-BEAM PARTICLE MICROSCOPE, ASSOCIATED COMPUTER PROGRAM PRODUCT AND MULTI-BEAM PARTICLE MICROSCOPE

(71) Applicant: Carl Zeiss MultiSEM GmbH, Oberkochen (DE)

(72) Inventor: David Disterheft, Aalen (DE)

(21) Appl. No.: 18/413,612

(22) Filed: Jan. 16, 2024

Related U.S. Application Data
(63) Continuation of application No. PCT/EP2022/025316, filed on Jul. 7, 2022.

(30) Foreign Application Priority Data
Jul. 20, 2021 (DE) 10 2021 118 684.6

(51) Int. Cl. H01J 37/147; H01J 37/04; H01J 37/28; H01J 37/304; H01J 37/317

(52) U.S. Cl. CPC H01J 37/1474; H01J 37/045; H01J 37/28; H01J 37/304; H01J 37/3177; H01J 2237/30477; H01J 2237/30488

(57) ABSTRACT

A method for analyzing disturbing influences in a multi-beam particle microscope which operates using a plurality of individual charged particle beams arranged in a raster arrangement includes the following steps: providing an object; stationary scanning the object at a first position via the plurality of the individual particle beams during a predetermined irradiation time T, as a result of which latent structures are formed on the object; raster scanning the object comprising the first position with the formed latent structures via the plurality of the individual particle beams; and analyzing the latent structures.

### CROSS-REFERENCE TO RELATED APPLICATIONS

The present application is a continuation of, and claims benefit under 35 USC 120 to, international application PCT/EP2022/025316, filed Jul. 7, 2022, which claims benefit under 35 USC 119 of German Application No. 10 2021 118 684.6, filed Jul. 20, 2021. The entire disclosure of each these applications is incorporated by reference herein.

### FIELD

The disclosure relates to a method for analyzing disturbing influences in a multi-beam particle microscope and to an associated computer program product and to an associated multi-beam particle microscope. The disturbing influences include for example acoustic, mechanical or magnetic disturbing influences.

### BACKGROUND

With the continuous development of ever smaller and ever more complex microstructures such as semiconductor components, it can be desirable to develop and optimize planar production techniques and inspection systems for producing and inspecting small dimensions of the microstructures. By way of example, the development and production of the semiconductor components involves monitoring of the design of test wafers, and the planar production techniques involve a process optimization for a reliable production with a high throughput. Moreover, there have been recent demands for an analysis of semiconductor wafers for reverse engineering and for a customer-specific, individual configuration of semiconductor components. Therefore, it is desirable to provide an inspection methodology which can be used with a high throughput for examining the microstructures on wafers with great accuracy.

Typical silicon wafers used in the production of semiconductor components have diameters of up to 300 mm. Each wafer is subdivided into 30 to 60 repeating regions (“dies”) with a size of up to 800 mm². A semiconductor apparatus comprises a plurality of semiconductor structures, which are produced in layers on a surface of the wafer by planar integration techniques. Semiconductor wafers typically have a plane surface on account of the production processes. The structure size of the integrated semiconductor structures in this case extends from a few um to the critical dimensions (CD) of 5 nm, wherein the structure sizes will become even smaller in the near future; in the future, structure sizes or critical dimensions (CD) are expected to be less than 3 nm, for example 2 nm, or even under 1 nm. In the case of the aforementioned small structure sizes, defects of the size of the critical dimensions are desirably identified quickly in a very large area. For several applications, the desired accuracy of a measurement provided by an inspection device can be even higher, for example by a factor of two or one order of magnitude. By way of example, a width of a semiconductor feature is desirably measured with an accuracy of below 1 nm, for example 0.3 nm or even less, and a relative position of semiconductor structures is determined with an overlay accuracy of below 1 nm, for example 0.3 nm or even less.

The MSEM, a multi-beam scanning electron microscope, is a relatively new development in the field of charged particle systems (charged particle microscopes, CPMs). By way of example, a multi-beam scanning electron microscope is disclosed in U.S. Pat. No. 7,244,949 B2 and in US 2019/0355544 A1. In the case of a multi-beam electron microscope or MSEM, a sample is irradiated simultaneously with a plurality of individual electron beams, which are arranged in a field or raster. By way of example, 4 to 10,000 individual electron beams can be provided as primary radiation, wherein each individual electron beam is separated from an adjacent individual electron beam by a pitch of 1 to 200 micrometers. By way of example, an MSEM has approximately 100 separated individual electron beams (“beamlets”), which are arranged for example in a hexagonal raster, wherein the individual electron beams are separated by a distance of approximately 10 μm. The plurality of individual charged particle beams (primary beams) are focused on a surface of a sample to be examined by way of a common objective lens. By way of example, the sample can be a semiconductor wafer which is fastened to a wafer holder that is mounted on a movable stage. During the illumination of the wafer surface with the charged primary individual particle beams, interaction products, for example secondary electrons or backscattered electrons, emanate from the surface of the wafer. Their start points correspond to those locations on the sample on which the plurality of primary individual particle beams are focused in each case. The amount and the energy of the interaction products generally depend on the material composition and the topography of the wafer surface. The interaction products form a plurality of secondary individual particle beams (secondary beams), which are collected by the common objective lens and which are incident on a detector arranged in a detection plane as a result of a projection imaging system of the multi-beam inspection system. The detector comprises a plurality of detection regions, each of which comprises a plurality of detection pixels, and the detector captures an intensity distribution for each of the secondary individual particle beams. An image field of, for example, 100 μm×100 μm is obtained in the process.

Certain known multi-beam electron microscopes comprise a sequence of electrostatic and magnetic elements. At least some of the electrostatic and magnetic elements are adjustable in order to adapt the focus position and the stigmation of the plurality of individual charged particle beams. Such multi-beam systems with charged particles moreover can comprise at least one cross-over plane of the primary or the secondary individual charged particle beams. Moreover, such systems can comprise detection systems to make the setting easier. Such multi-beam particle microscopes can comprise at least one beam deflector (“deflection scanner”) for the collective scanning of a region of the sample surface via the plurality of primary individual particle beams in order to obtain an image field of the sample surface. Further details regarding a multi-beam electron microscope and a method for operating same are described in the German patent application with the application number 102020206739.2, filed on May 28, 2020, the disclosure of which is incorporated in full in the present application by reference.

In order to acquire high-resolution images and/or to be able to carry out highly accurate measurements of structures using a multi-beam scanning electron microscope or, more generally, using a multi-beam particle microscope, the knowledge of and, if possible, the elimination of disturbing influences that reduce the performance and/or the (high) resolution of the microscopes is an important aspect. These disturbing influences can be, for example, of an acoustic and/or mechanical nature, for example noise or vibrations due to pumps in the laboratory or ventilator noise. Even magnetic disturbing influences brought about primarily by electrical or electromagnetic effects of other devices (EMC) may occur. However, disturbing influences brought about by passing trucks or cars or by moving metal gates are also possible. All these disturbing influences can easily cause changes in the trajectories or incidence locations of the individual particle beams on the sample, and the resolution may deteriorate.

Certain known time-consuming measurements on test samples are performed in order to quantify disturbing influences or to assess the stability of the multi-beam particle microscopes. Using a plurality of measurements in which the test sample is raster-scanned, the resolution of the multi-beam particle microscope is determined; these measurements typically take several hours overall to acquire a sufficient amount of data for the statistical analysis that follows. The algorithms used for this purpose are relatively complex, and their application is therefore relatively time-consuming. In addition, the ambient parameters of the multi-beam particle microscope are desirably be kept exactly constant during the measurements, the system runs constantly; if not, the effects of disturbing influences cannot be determined with sufficient accuracy. Further, certain known methods are relatively resource-intensive because many test samples are used, which can each be scanned and thus used only once.

The occurrence of systematic errors due to the raster-scanning itself also is to be taken into account. The particle beams interact with the sample and thereby generate secondary beams that emerge from the sample with a slight time delay and frequently in a cascade-type manner. The signal obtained for a specific pixel is therefore, strictly speaking, dependent on the previously scanned structure. A practical consequence of this can be that a measured line width or edge of a structure is dependent on the direction in which scanning over the line or edge took place. Ideally, this systematic error caused by the scanning direction likewise is to be taken into account or corrected by algorithms. This can make the analysis of disturbing influences on the multiple particle beam system even more difficult.

DE 10 2018 210 522 A1 discloses a method for examining a beam of charged particles, including the following steps: producing persistent interactions of the beam with a sample at a plurality of positions of the sample relative to the beam and deriving at least one property of the beam by analysing the spatial distribution of the persistent interactions at the plurality of positions. The patent application is thus related to a single beam device. Furthermore, it does not deal with ambient or external disturbing influences on a particle microscope, but it is related to disturbing influences inherently present in a particle microscope. DE 10 2018 210 522 A1 discloses a beam induced deposition of a precursor material and other interaction mechanisms such as beam induced etching or irradiating electron-sensitive lacquer layers or polymer substrates which modify the sample with the beam in a permanent way. It is noted that either a specific material is added for later analyzation purposes or that a specific sample has to be used to enable an analysis of the persistent interactions of the beam with the sample.

### SUMMARY

The disclosure seeks to improve the existing methods for analyzing disturbing influences in multi-beam particle microscopes, wherein these disturbing influences are ambient or external influences and therefore influences that do not have their origin in the multi-beam particle microscope per se. The methods according to the disclosure are intended to operate more simply, faster, more precisely and in a more resource-saving manner. Furthermore, the method can be applicable in a universal way.

The disclosure uses here an effect that has not previously been known. If a sample or an object is irradiated in a stationary manner with individual charged particle beams over a relatively long period of time, i.e. with a high dose (charge density), latent structures are formed thereby on the object, that is to say structures that disappear again after some time, they are thus not persistent. In general, these structures can be analyzed, that is to say raster-scanned, in the manner that is customary for multi-beam particle microscopes.

It has been found here that the latent structures that have formed can image or even monitor disturbing influences. This is because the latent structures arise in general at the locations at which the individual particle beams interact with the object. If individual particle beams migrate or move over an object or an object surface due to a disturbing influence, the latent structures that are formed in the process can image this migratory movement and thus make it measurable.

It is noted that according to the present disclosure no additional substances as in DE 10 2018 210 522 A1 have to be added to make the disclosure work, for example no precursor material has to be used.

According to a first aspect, the disclosure provides a method for analyzing disturbing influences in a multi-beam particle microscope which operates using a plurality of individual charged particle beams arranged in a raster arrangement, wherein the method includes the following steps: providing an object; stationary scanning the object at a first position via the plurality of the individual particle beams during a predetermined irradiation time T, as a result of which latent structures are formed on the object; raster-scanning the object comprising the first position with the formed latent structures via the plurality of the individual particle beams; and analyzing the latent structures.

The individual charged particle beams can be, for example, electrons, positrons, muons or ions or other charged particles.

The multi-beam particle microscope can be a system operating with an individual column, but it is also possible that the multi-beam particle microscope is implemented via a multi-column system. The individual particle beams are arranged here in a raster arrangement, that is to say an arrangement of the individual particle beams in relation to one another can be fixed or can be selected. This can be a regular raster arrangement, which can provide, for example, a square, rectangular or hexagonal arrangement of the individual particle beams in relation to one another, for example with uniform spacing. It can be advantageous if the number of the individual particle beams is 3 n (n−1)+1, where n is any natural number.

The methods according to the disclosure can suitable for analyzing disturbing influences and is used for analyzing disturbing influences. These disturbing influences can be mechanical, acoustic and/or magnetic disturbing influences. Acoustic disturbing influences for example also comprise vibrations, which can represent an important disturbing influence. Other types of disturbing influences can also be examined and analyzed via the method according to the disclosure.

Scanning or irradiating the object takes place in a stationary manner at a first position. That means that a position of the individual particle beams is not actively changed upon incidence on the object. Any variations in the position of the individual particle beams on the object are therefore solely due to disturbing influences that are present in the multi-beam particle microscope. The beam current of the individual particle beams can also be kept constant during the stationary scanning of the object.

The duration of the irradiation time T can be set in advance, wherein the setting is based for example on experiential knowledge gained in prior measurements. According to an embodiment of the disclosure, the following applies to the irradiation time T in the first position: 0.1 s≤T≤5 s, such as 0.5 s≤T≤2 s. The irradiation time is significantly longer than a dwell time per pixel when performing a conventional raster scan of an object, yet the irradiation time T in this first position is so short that ambient parameters of the multi-beam particle microscope can be considered to be constant. System drifts do not play any role during the stationary scan. In addition, the overall time for performing the method according to the disclosure is very short in comparison with conventional methods as described above in the introductory part of the description. In addition, owing to the stationary scan of the object, a systematic error due to the scanning direction is eliminated, which offers further advantages in the analysis of disturbing influences.

According to an embodiment of the disclosure, the following relationship exists for a dose Dₛₜₐₜ during the stationary scanning of the object in the first position and for a dose Dᵣₐₛₜ during the raster scanning of the object comprising the first position: 1,000 Dᵣₐₛₜ≤Dₛₜₐₜ≤100,000 Dᵣₐₛₜ, such as 10,000 Dᵣₐₛₜ≤Dₛₜₐₜ≤100,000 Dᵣₐₛₜ. The dose during the stationary scanning or when irradiating the object at the first position is thus 10,000 to 100,000 times, for example 25,000 times, greater than during the raster scanning of the object. A typical dose during the stationary scanning at an irradiation time T of 0.5 s is, for example, 10⁻¹² C/nm². In contrast, a dose during a raster scanning of the object at a dwell time per pixel of approximately 20 ns to 50 ns for a pixel size of 0.5 nm×0.5 nm at approximately 570 pA is approximately 4×10⁻¹⁷ C/nm² to 1×10⁻¹⁶ C/nm². This corresponds to approximately 300 to 700 electrons or charged particles per nm².

In an interaction with the object, a significantly greater effect is produced by way of the higher energy input than during a measurement or during a raster scan of the object. It is possible that the latent effect also occurs during the raster scan, but it is not observable but is lost in the noise of the measurement. However, it is also possible to use samples for which the effect occurs in the first place only at the higher dose used during the stationary scan of the object; these are in particular phase transitions.

The nature of the latent structures is dependent on the type of the object provided. Some objects are better suited for forming latent structures than other objects. Possible mechanisms for forming the latent structures will be discussed in more detail further below. A latency time of the latent structures can be, for example, more than 10 minutes, such as more than 1 hour or more than 3 hours, but can also be even longer. According to an example, the latency time is shorter than 24 hours, 12 hours, 6 hours, 2 hours or even shorter than 1 hour or 30 minutes or 15 minutes. The latency time is preferably defined here such that the observable manifestation of the latent structures decreases greatly after the time period has expired, for example has decayed to the fraction 1/e. The latency time can also define the time within which an analysis of the latent structures is actually still possible. After that, the latent structures disappear again and are no longer analyzable. The structures are thus not persistent.

After the latent structures have been formed by the stationary scan of the object, a raster scan of the object comprising the first position with the formed latent structures is performed according to the disclosure via the plurality of individual particle beams. The scan in this case comprises the first position with the formed latent structures, that is to say the region that is scanned is selected to be so large that the formed latent structures can be raster-scanned in particular completely. Owing to disturbing influences, the formed latent structures can have greater dimensions than the beam diameter or the interaction cross section of the individual particle beams with the sample. The latent structures formed trace, as it were, the disturbing influences on the object, and a slight migration or wobbling at the individual particle beam for example due to vibrations can thus be made visible.

In a further method step, the latent structures are analyzed. In doing so, for example their size and/or their geometry can be determined. The latent structures can here be formed in the manner of lines, circular, in the shape of an ellipse with different inclination of the major axis of the ellipse or star-shaped or have a different form. The size and/or geometry of the latent structures then allow conclusions to be drawn regarding the magnitude and possibly also the nature of the disturbing influences.

According to an embodiment of the disclosure, the analysis of the latent structures comprises determining deflections of the individual particle beams from an equilibrium position. If there are no disturbing influences in the vicinity or in a multi-beam particle microscope, latent structures in the shape of dots or with a circular cross section are expected in general. A deviation from this shape corresponds to a deflection of the individual particle beams during the irradiation process and is therefore a measure of a disturbing influence. In the case of vibrations, the movement or deflection of the individual particle beams takes place around the equilibrium position thereof, for example.

Deflections can be determined on the basis of a nominal or undisturbed beam diameter of the individual particle beams and/or on the basis of a nominal or undisturbed interaction cross section of the individual particle beams upon incidence on the object. In an ideal case, the undisturbed beam diameter is here identical to the undisturbed interaction cross section, while in practice, the interaction cross section is frequently slightly greater than the beam diameter because interactions of the charged particles in the sample take place not only ideally in the direction of the depth (z-direction) but also laterally, and in particular cascade-type collision processes of the secondary particles also occur. It is for example also possible via the method according to the disclosure to check whether a nominal, i.e., for example, as specified by the producer, beam diameter or interaction cross section is also in fact achieved. If this is not the case, disturbing influences can be once again inferred and corresponding measures can be taken.

According to an embodiment of the disclosure, the method includes moreover the following step: switching a disturbing influence on and/or off.

For example, it is possible to switch a magnetic field on and off in a targeted manner, for example by provided Helmholtz coils. In general, it is possible in this way to assess the influence of magnetic disturbances on the multi-beam particle microscope. It is possible to find out whether special shielding measures for the multi-beam particle microscope make sense. In addition, it is thus possible to systematically examine the magnitude of a disturbing influence (here: magnetic field) on the performance of the multi-beam particle microscope. The type and size of the formed latent structures are dependent on the type and/or magnitude of the disturbing influence.

According to an embodiment of the disclosure, a disturbing influence is quantified on the basis of the analysis of the latent structures. It is possible to draw conclusions regarding the magnitude of the disturbance from known relationships between the disturbing influence and the latent structures that then occur.

According to an embodiment of the disclosure, a pause time TP between the stationary scan of the object in the first position and the raster scan of the object comprising the first position is set. The pause time TP can be selected here for example such that disturbing influences that were switched on in a targeted manner during the stationary scan can also be switched off again in the pause time TP so that the disturbing influences do not disturb the subsequent raster scan. In this case, the pause time can be, for example, a few milliseconds or seconds, e.g. 1 ms, 5 ms, 1 s, 2 s or 3 s. Optionally, the pause time TP is very short if the raster-scanning of the object takes place directly after the stationary scan. Without switch-off processes of disturbing influences, the pause time TP can then be, for example, a few nanoseconds or microseconds, for example 50 ns, 200 ns, 1 μs, 2 μs or 3 μs. However, it is also possible that a pause time TP of several minutes is selected. This can be the case if the object is initially scanned only in a stationary manner at one or more positions and the raster-scanning of the object does not take place until later. It is theoretically also possible for the object to be temporarily removed from the sample holder, but this temporary removal is not advantageous. If the stationary scan and the raster scan are performed in quick succession, the position at which the stationary scan took place and at which the raster scan is now to take place is known exactly. Moving the system to the first position once again can be dispensed with, which increases the precision of the method according to the disclosure.

According to an embodiment of the disclosure, the multi-beam particle microscope comprises a collective scan deflector, which is configured to collectively move the raster arrangement of the plurality of individual particle beams over an object surface in a raster-type manner. The raster-scanning of the object then comprises suitably controlling the collective scan deflector, and the stationary scanning of the object comprises stopping or switching off the collective scan deflector. In this way, the method according to the disclosure can be carried out particularly easily via a conventional multi-beam particle microscope. The collective scan deflector can be correspondingly controlled via a corresponding controller. The way in which a collective scan deflector can be controlled is already known. Examples of this and further details are described, for example, in the patent application with the application number PCT/EP2021/052293, filed on Feb. 1, 2021, which was not yet laid-open at the priority date of the present patent application and the disclosure of which is incorporated in full in the present patent application by reference.

When a collective scan deflector is stopped or switched off, the individual particle beams are typically positioned, with reference to the single field of view (sFOV), centrally in the single field of view. When the single field of view is raster-scanned, the position of the individual particle beams in the single field of view is run through (raster-scanned) systematically from, for example, an upper corner to a lower corner. Such a configuration of a collective scan deflector can be desirable for the method according to the disclosure because, in that case, when the collective scan deflector is switched off or stopped, the first position during the stationary scan of the object corresponds to the central position of the individual particle beams. When the collective scan deflector is switched on or used again, the raster scan of the object comprising the first position with the formed latent structures then takes place quasi automatically.

According to an embodiment of the disclosure, the multi-beam particle microscope has a collective beam blanker, which is configured to collectively deflect the plurality of the individual particle beams in a manner such that they are not incident on the object, in particular are incident on a beam stop, and the stationary scan of the object comprises releasing the beam blanker while the scan deflector is stopped so that the plurality of the individual particle beams are incident on the object. A controller can in this case correspondingly control the collective beam blanker. In contrast to known systems, the collective beam blanker is thus released not only if the object is raster-scanned with the individual charged particle beams. Rather, the individual particle beams are also released during the stationary scan of the object for forming the latent structures on the object. For this purpose, corresponding control signals can be used.

According to an embodiment of the disclosure, a full single field of view (sFOV) or only a partial region of a single field of view (sFOV) is raster-scanned by each individual particle beam during the raster scan of the object comprising the first position. According to an embodiment of the disclosure, the size of the region of a single field of view (sFOV) to be raster-scanned is defined on the basis of the magnitude of a disturbing influence and/or on the basis of properties of the object. The method can be made faster overall in this way. The size of the region to be raster-scanned can be selected such that latent structures can be raster-scanned completely. However, it is not necessary to raster-scan regions in which these latent structures are not present. Raster-scanning those regions would provide no additional information during the analysis of the disturbing influences.

According to an embodiment of the disclosure, the stationary scanning takes place centrally in a single field of view (sFOV) and/or in an equilibrium position of the individual particle beams in the raster arrangement. In this way, an analysis of the latent structures is possible particularly easily.

According to an embodiment of the disclosure, the method moreover includes the following step: compensating the disturbing influences.

This may involve structural measures for example around the multi-beam particle microscope. For example, it is possible to shield the multi-beam particle microscope in a targeted manner so as to eliminate disturbing influences. However, it is also possible that uncontrollable disturbing influences that are characteristic are compensated in a targeted manner by specifically produced further disturbing influences. These include magnetic fields, for example.

According to an embodiment of the disclosure, the method furthermore includes the following step: adjusting the multi-beam particle microscope on the basis of the analyzed latent structures.

It is possible, for example, that the individual particle beams have an astigmatism owing to a disturbing influence. If it is not possible to eliminate the disturbing influence itself, appropriately adjusting the multi-beam particle microscope can result in the astigmatism caused by the disruption to be compensated by way of a fine adjustment.

According to an embodiment of the disclosure, the latent structures are generated by way of stationary charges on the object. Stationary charges on an object are possible in general in all objects or samples used. However, the latency times or decay times in the case of charging effects are dependent on the object itself. For example, if a semiconductor wafer is used as the object, for example the critical layers have many small, insulated structures or poorly conducting surfaces, which means that the latter lose local charges relatively slowly only via diffusion currents or leakage currents.

According to an embodiment of the disclosure, the latent structures are generated by topographic effects on the basis of structural changes on the sample. For example, it is possible to change a crystal structure of the sample and/or to compact the object by way of the stationary scan. It is also possible that the object undergoes a phase transition on the surface, for example a magnetization of the object can be reversed. Phase transitions can have the advantage that they occur on the one hand suddenly and, on the other, only after a specific dose has been provided. This type of structural change therefore does not occur at all when the sample is raster-scanned. In addition, phase transitions are normally reversible, and an object can therefore possibly be used multiple times.

According to an embodiment of the disclosure, the latent structures are generated by chemical changes on the sample. To this end, the surface of the sample can oxidize, for example, and/or it is possible to crack structures, for example hydrocarbons, on the surface and arrange them differently.

According to an embodiment of the disclosure, the latent structures are generated by energetic excitations. During the subsequent raster scan, the response function of the object to the bombardment with charged particles is thereby modified, as a result of which an image contrast becomes visible.

It is also possible to produce the latent structures in a different way than described above. It is not the scientific mechanism allowing the production latent structures that is important but their existence and measurability.

According to an embodiment of the disclosure, the latent structures are produced exclusively by irradiating the object with the plurality of individual particle beams and without supplying process gas. The fact that no process gas is added for the production of latent structures is of particular importance in semiconductor inspection where any introduction of chemical substances into a process chamber is to be regarded. Furthermore, resources can be saved if no process gas is used and no specific technical measures have to be taken for a gas supply.

According to an embodiment of the disclosure, the method furthermore includes the following step: stationary scanning the object at a second position via the plurality of the individual particle beams during the predetermined irradiation time T, as a result of which latent structures are formed on the object; raster-scanning the object comprising the second position with the formed latent structures via the plurality of the individual particle beams.

Everything that was already stated in connection with the stationary scan of the object at the first position and the raster scan of the object comprising the first position also applies to the stationary scan of the object at the second position and the raster scan of the object comprising the second position. The method can also be carried out in a corresponding manner for a third position, a fourth position and generally for many positions. For each of these positions, the latent structures can be analyzed.

Generally it is possible to carry out the above-described method in its various embodiment variants multiple times. In doing so, the described exemplary embodiments of the disclosure can be combined with one another in full or in part, provided that no technical contradictions arise as a result.

According to a second aspect, the disclosure provides a computer program product having a program code for carrying out the method as claimed in any one of the preceding claims. In this case, the program code can be subdivided into one or more partial codes. The code can be written in any desired programming language.

According to a third aspect, the disclosure provides a multi-beam particle microscope having a controller, which is configured to control the multi-beam particle microscope according to the method as described above in conjunction with the first aspect of the disclosure in a plurality of embodiment variants.

According to a fourth aspect, the disclosure provides a multi-beam particle microscope, such as a multi-beam particle microscope as described according to the third aspect, the method including the following features: a multi-beam generator, which is configured to generate a first field of a plurality of charged first particle beams; a first particle optical unit with a first particle-optical beam path, which is configured to image the generated individual particle beams onto a sample surface in the object plane such that the first particle beams are incident on the sample surface at incidence locations which form a second field; a detection system with a plurality of detection regions which form a third field; a second particle optical unit with a second particle-optical beam path, which is configured to image second individual particle beams, which emanate from the incidence locations in the second field, onto the third field of the detection regions of the detection system; a magnetic and/or electrostatic objective lens, through which both the first and the second individual particle beams pass; a beam switch, which is arranged in the first particle-optical beam path between the multi-beam generator and the objective lens and which is arranged in the second particle-optical beam path between the objective lens and the detection system; a collective scan deflector, which is arranged between the beam switch and the sample surface and configured to collectively raster-scan the sample surface using the plurality of charged first particle beams;

a mode-selection device, in particular a control panel, for selecting an analysis operating mode, in which latent structures are producible on a sample; and a controller, wherein the controller is configured to control the collective scan deflector in the analysis operating mode such that a stationary scan of the object at a predefined position takes place via the plurality of the individual particle beams during a predetermined irradiation time T, as a result of which latent structures are formed on the object; and wherein the controller is configured to control the collective scan deflector in the analysis operating mode after the stationary scan such that a raster scan of the object comprising the predefined position with the formed latent structures takes place via the plurality of the individual particle beams.

The multi-beam particle microscope is thus especially preconfigured such that a user can operate the microscope very easily in the analysis operating mode, in which latent structures are producible on the object. It is also possible to provide further control panels that permit, for example, the individual input or selection of parameters that are characteristic of the analysis operating mode. These include, for example, the irradiation time T, the pause time TP and/or the size of the region of a single field of view (sFOV) that is to be raster-scanned. The selection or input of other or further parameters can likewise be possible.

According to an embodiment of the disclosure, the following relationship exists for a dose Dₛₜₐₜ during the stationary scan of the object in the first position and for a dose Dᵣₐₛₜ during the raster scan of the object comprising the first position: 1,000 Dᵣₐₛₜ≤Dₛₜₐₜ≤100,000 Dᵣₐₛₜ, such as 10,000 Dᵣₐₛₜ≤Dₛₜₐₜ≤100,000 Dᵣₐₛₜ.

According to an embodiment of the disclosure, the multi-beam particle microscope furthermore has a collective beam blanker, which is configured to deflect the plurality of the first individual particle beams in a manner such that the first individual particle beams are not incident on the sample, in particular are incident on a beam stop. The controller is configured here to control the collective beam blanker in the analysis operating mode such that a stationary scan of the object at the predefined position takes place via the plurality of the individual particle beams during the predetermined irradiation time T with a released beam blanker. In contrast to conventional configurations or in contrast to a conventional process control via multi-beam particle microscopes, the collective beam blanker is thus released or is inactive not only when the raster scan of the object takes place. Rather, the collective deflection/blanking is also interrupted when the stationary scan of the object for producing the latent structures is carried out.

According to a fifth aspect, the disclosure provides a method for producing marker structures on an object, in particular on a semiconductor sample, via a multi-beam particle beam system operating with a plurality of individual charged particle beams, the method including the following step: stationary irradiating the object with the plurality of individual particle beams during a predetermined irradiation time T, as a result of which latent structures are formed in the form of marker structures on the object.

The use of marker structures for alignment purposes and/or registration processes is generally customary. However, until now, these have been permanently applied structures, rather than latent structures. The use of latent structures as marker structures has the advantage that they can be incorporated in a workflow according to which a sample to be examined or an object to be examined is raster-scanned in conventional fashion. Owing to the sequence of producing the marker structures and, optionally immediately following it, raster-scanning the object, it is possible to provide the marker structure in the same coordinate or reference system in which the actual measurement/scanning is also performed. It is therefore possible to determine more accurately a position of the structures of the object with reference to the marker structure.

In order to produce arbitrarily shaped marker structures, the above-described collective scan deflector can be used, for example. The object is then irradiated in a stationary manner at different positions per individual particle beam. In addition or alternatively, it is also possible to change a raster arrangement of the individual particle beams for producing the marker structures. The raster arrangement can be formed in that case not only regularly but also irregularly. For example, with an appropriate setting of the raster arrangement, numbers or letters can be produced as latent structures on the object in particular in a single irradiation step. Details regarding the production of an irregular raster arrangement are described, for example, in the German patent application with the application number 10 2021 116 969.0, which was not yet laid-open at the priority date of the present patent application and the disclosure of which is incorporated in full in the present patent application by reference.

Everything that was already stated above in detail in connection with the first to fourth aspects of the disclosure also applies to the stationary irradiation of the object with the plurality of individual particle beams during a predetermined irradiation time T, as a result of which latent structures are formed as marker structures on the object.

The various embodiment variants of the disclosure according to the first to fifth aspects of the disclosure can be combined with one another in full or in part, provided that no technical contradictions arise as a result.

### BRIEF DESCRIPTION OF THE DRAWINGS

The disclosure will be understood even better with reference to the accompanying figures, in which:

FIG. 1: shows a schematic illustration of a multi-beam particle microscope (MSEM);

FIG. 2: shows a workflow of a method according to the disclosure for quantifying disturbing influences in a multi-beam particle microscope;

FIG. 3: schematically illustrates the widening of an interaction zone;

FIG. 4: schematically shows different geometries of latent structures on an object; and

FIG. 5: schematically shows latent structures of a raster arrangement of individual particle beams.

### DETAILED DESCRIPTION

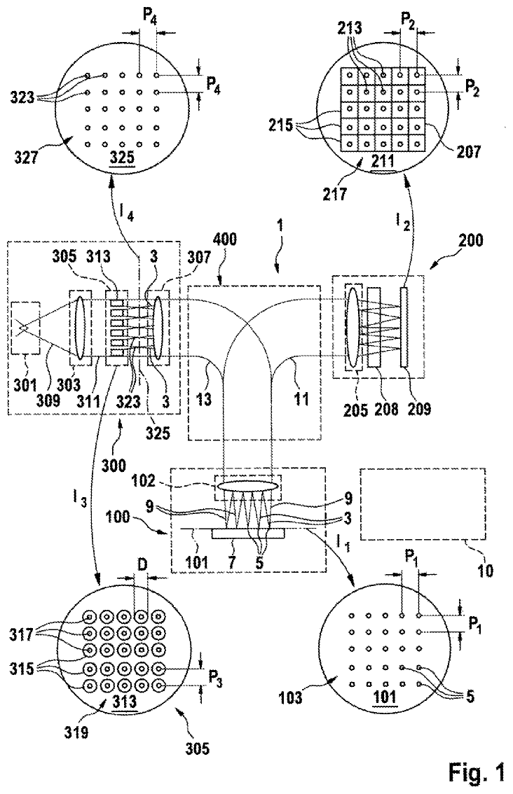

FIG. 1 is a schematic illustration of a particle beam system 1 in the form of a multi-beam particle microscope 1, which uses a plurality of particle beams. The particle beam system 1 generates a plurality of particle beams which are incident on an object to be examined in order to generate there interaction products, e.g., secondary electrons, which emanate from the object and are subsequently detected. The particle beam system 1 is of the scanning electron microscope (SEM) type, which uses a plurality of primary particle beams 3 which are incident on a surface of the object 7 at a plurality of locations 5 and produce there a plurality of electron beam spots, or spots, that are spatially separated from one another. The object 7 to be examined can be of any desired type, e.g., a semiconductor wafer or a biological sample, and comprise an arrangement of miniaturized elements or the like. The surface of the object 7 is arranged in a first plane 101 (object plane) of an objective lens 102 of an objective lens system 100.

The enlarged detail Il in FIG. 1 shows a plan view of the object plane 101 having a regular rectangular field 103 of incidence locations 5 formed in the first plane 101. In FIG. 1, the number of incidence locations is 25, which form a 5×5 field 103. The number 25 of incidence locations is a number chosen for reasons of simplified illustration. In practice, the number of beams, and hence the number of incidence locations, can be chosen to be significantly greater, such as, for example, 20×30, 100×100 and the like.

In the depicted embodiment, the field 103 of incidence locations 5 is a substantially regular rectangular field having a constant spacing P1 between adjacent incidence locations. Exemplary values of the spacing P1 are 1 micrometer, 10 micrometers and 40 micrometers. However, it is also possible for the field 103 to have other symmetries, such as a hexagonal symmetry, for example.

A diameter of the beam spots formed in the first plane 101 can be small. Exemplary values of the diameter are 1 nanometer, 5 nanometers, 10 nanometers, 100 nanometers and 200 nanometers. The focusing of the particle beams 3 for shaping the beam spots 5 is carried out by the objective lens system 100.

The primary particles incident on the object generate interaction products, e.g., secondary electrons, backscattered electrons or primary particles that have experienced a reversal of movement for other reasons, which emanate from the surface of the object 7 or from the first plane 101. The interaction products emanating from the surface of the object 7 are shaped by the objective lens 102 to form secondary particle beams 9. The particle beam system 1 provides a particle beam path 11 for guiding the plurality of secondary particle beams 9 to a detector system 200. The detector system 200 comprises a particle optical unit with a projection lens 205 for directing the secondary particle beams 9 at a particle multi-detector 209.

The detail 12 in FIG. 1 shows a plan view of the plane 211, in which individual detection regions of the particle multi-detector 209 on which the secondary particle beams 9 are incident at locations 213 are located. The incidence locations 213 lie in a field 217 with a regular spacing P2 from one another. Exemplary values of the spacing P2 are 10 micrometers, 100 micrometers, and 200 micrometers.

The primary particle beams 3 are produced in a beam generating apparatus 300 comprising at least one particle source 301 (e.g., an electron source), at least one collimation lens 303, a multi-aperture arrangement 305 and a field lens 307. The particle source 301 produces a diverging particle beam 309, which is collimated or at least substantially collimated by the collimation lens 303 in order to shape a beam 311 which illuminates the multi-aperture arrangement 305.

The detail 13 in FIG. 1 shows a plan view of the multi-aperture arrangement 305. The multi-aperture arrangement 305 comprises a multi-aperture plate 313, which has a plurality of openings or apertures 315 formed therein. Midpoints 317 of the openings 315 are arranged in a field 319 that is imaged onto the field 103 formed by the beam spots 5 in the object plane 101. A spacing P3 between the midpoints 317 of the apertures 315 can have exemplary values of 5 micrometers, 100 micrometers, and 200 micrometers. The diameters D of the apertures 315 are smaller than the spacing P3 between the midpoints of the apertures. Exemplary values of the diameters D are 0.2×P3, 0.4×P3, and 0.8×P3.

Particles of the illuminating particle beam 311 pass through the apertures 315 and form particle beams 3. Particles of the illuminating beam 311 which are incident on the plate 313 are absorbed by the latter and do not contribute to the formation of the particle beams 3.

On account of an applied electrostatic field, the multi-aperture arrangement 305 focuses each of the particle beams 3 in such a way that beam foci 323 are formed in a plane 325. Alternatively, the beam foci 323 can be virtual. A diameter of the beam foci 323 can be, for example, 10 nanometers, 100 nanometers and 1 micrometer.

The field lens 307 and the objective lens 102 provide a first imaging particle optical unit for imaging the plane 325, in which the beam foci 323 are formed, onto the first plane 101 such that a field 103 of incidence locations 5 or beam spots arises there. Should a surface of the object 7 be arranged in the first plane, the beam spots are correspondingly formed on the object surface.

The objective lens 102 and the projection lens arrangement 205 provide a second imaging particle optical unit for imaging the first plane 101 onto the detection plane 211. The objective lens 102 is thus a lens that is part of both the first and the second particle optical unit, while the field lens 307 belongs only to the first particle optical unit and the projection lens 205 belongs only to the second particle optical unit.

A beam switch 400 is arranged in the beam path of the first particle optical unit between the multi-aperture arrangement 305 and the objective lens system 100. The beam switch 400 is also part of the second optical unit in the beam path between the objective lens system 100 and the detector system 200.

Further information relating to such multi-beam particle beam systems and components used therein, such as, for instance, particle sources, multi-aperture plate and lenses, can be obtained from the international patent applications WO 2005/ 024881 A2, WO 2007/028595 A2, WO 2007/028596 A1, WO 2011/124352 A1 and WO 2007/060017 A2 and the German patent applications DE 10 2013 016 113 A1 and DE 10 2013 014 976 A1, the disclosure of which is incorporated in full in the present application by reference.

The multiple particle beam system furthermore comprises a computer system 10, which is configured both for controlling the individual particle-optical components of the multiple particle beam system and for evaluating and analyzing the signals obtained by the multi-detector 209. It can also be used to carry out the method according to the disclosure. The computer system 10 can for this purpose control in particular a collective scan deflector (not illustrated) and a collective beam blanker (not illustrated) for carrying out the method according to the disclosure. The computer system 10 can be constructed from a plurality of individual computers or components.

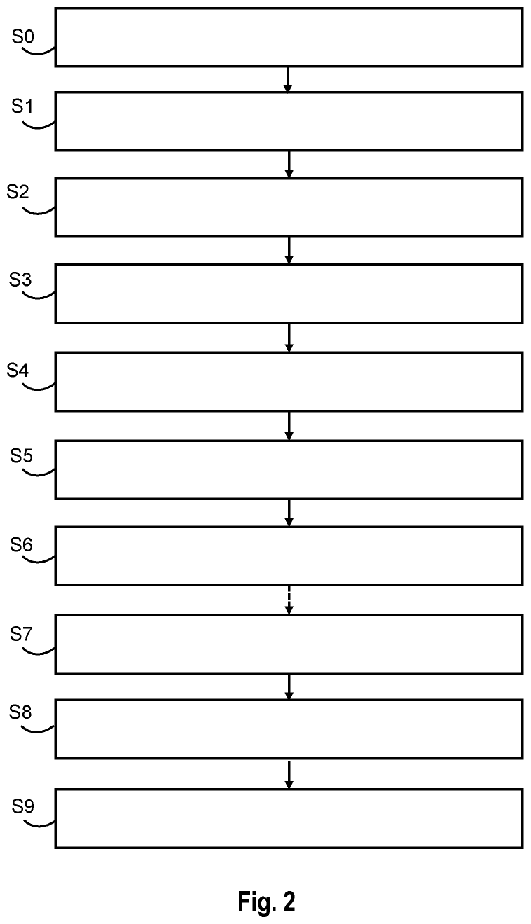

FIG. 2 shows an example of a workflow of a method according to the disclosure for analyzing disturbing influences in a multi-beam particle microscope. The multi-beam particle microscope 1 operates with a plurality of individual charged particle beams 3, for example electrons, which are arranged in a raster arrangement. In the example described, the multi-beam particle microscope 1 comprises a collective scan deflector, which is set up to collectively move the raster arrangement of the plurality of individual particle beams over an object surface in a raster-type manner. The multi-beam particle microscope furthermore has a collective beam blanker, which is set up to collectively deflect the plurality of individual particle beams such that they are not incident on the object but are incident on a beam stop.

Initially, the object is provided in a method step S0. The object 7 can be, for example, a semiconductor wafer, but the use of other samples or objects is also possible.

In a method step S1, the multi-beam particle microscope 1 is used to home in on a first position. For this purpose, the multi-beam particle microscope 1 is aligned in relation to the object 7, for example by moving the sample holder/the stage.

Once the homing-in on the first position has taken place, the object 7 is scanned in a stationary manner in a method step S2 at the first position via the plurality of the individual particle beams 3 during a predetermined irradiation time T, as a result of which latent structures 51 are formed on the object 7. In the depicted example, the irradiation time T is one second, but can also be selected to be shorter or longer. The selection of the irradiation time T can be made dependent, for example, on the type of the sample 7 and on the beam current of the individual particle beams 3. It is ultimately the dose Dₛₜₐₜ during the stationary scan of the object 7 that is important. This dose Dₛₜₐₜ is greater by a multiple than the dose Dᵣₐₛₜ during the raster scan of the object 7 comprising the first position. Typically, the dose Dₛₜₐₜ is between 1000 times and 100 000 times greater than the dose Dᵣₐₛₜ.

By scanning the object 7 in a stationary manner at the first position, latent structures 51 are formed on the object 7. The latent structures 51 can be produced, for example, by stationary charges on the object 7. After they have been produced, they are visible for some time before they fade and ultimately become invisible. Typical latency times are more than 10 minutes, in particular more than 1 hour or more than 3 hours, but can also be even longer. It is also possible for the latent structures to be produced by other effects than by stationary charges on the object. Examples of this are topographic effects based on structural changes on the sample and/or chemical changes on the sample.

In a further method step S3, raster-scanning of the object 7 comprising the first position with the formed latent structures 51 is effected via the plurality of the individual particle beams 3. Now, the latent structures 51 are thus scanned in a manner that is already known. For this purpose, the collective scan deflector is used in the described example, which can raster-scan for example a full single field of view (sFOV) per individual particle beam 3, although it is also possible that only a partial region of a single field of view (sFOV) per individual particle beam 3 is raster-scanned via the collective scan deflector. The size of the region of a single field of view that is to be raster-scanned can here be set on the basis of the magnitude of a disturbing influence and/or of properties of the object.

In a further method step S4, the individual particle beams 3 are blanked, and a second position is homed in on by the multi-beam particle microscope 1. The second relative position between the multi-beam particle microscope 1 and the object 7 can here be homed in on for example by a movement of the sample carrier or stage.

Once the second position has been reached, the object 7 is scanned in a stationary manner in a method step S5 at the second position via the plurality of the individual particle beams 3 during the predetermined irradiation time T, as a result of which latent structures 51 are again formed on the object 7. In order to scan the object 7 in a stationary manner, in particular the collective beam blanker is released so that the plurality of the individual particle beams 3 are incident on the object 7. The collective scan deflector is not active, or has been interrupted, during the stationary scan of the second position.

In a further method step S6, raster-scanning of the object 7 comprising the second position with the formed latent structures 51 is effected via the plurality of the individual particle beams 3. For this purpose, the collective scan deflector is controlled such that the respective individual particle beams 3 raster-scan the image field (sFOV) associated therewith in full or partially.

In further method steps (not illustrated explicitly), further positions can be homed in on, which are initially scanned in a stationary manner and are then scanned in a raster-type manner. This is continued until, in a further method step S7, the last position n is homed in on, the position n is scanned in a stationary manner and is subsequently scanned in a raster-type manner.

Then, in a further method step S8, the latent structures 51 are analyzed. To analyze the latent structures 51, they can be in particular measured. Analyzing the latent structures 51 can here comprise for example determining deflections of the individual particle beams 3 from an equilibrium position. This equilibrium position is, for example, a position centrally in a single field of view (sFOV), in which the individual particle beams 3 are naturally situated when the collective scan deflector is switched off. What happens due to disturbing influences is that the beam path or the incidence location of the individual particle beams 3 on the object 7 is varied. This causes the formation of latent structures 51 on the object 7, which are not only in the equilibrium position, that is to say situated centrally in the single field of view, and/or which are not only point-shaped or circular. Depending on the magnitude of the disturbing influences, the produced latent structures 51 are larger and show for example oscillations as disturbing influences. Deflections from the equilibrium position can be determined, for example, on the basis of a nominal or undisturbed beam diameter of the individual particle beams 3 and/or on the basis of a nominal or undisturbed interaction cross section of the individual particle beams 3 upon incidence on the object 7. The extent of this deflection is then a measure of the magnitude of the identified disturbing influences. If the disturbing influence is large, the deflection will also be large, and vice versa.

In a further optional method step S9, the disturbing influence is quantified on the basis of the analysis of the latent structures. This quantification can be, for example, the relationship between the disturbed beam diameter of the individual particle beams and the nominal or undisturbed beam diameter of the individual particle beams. A further example is the relationship between the interaction cross section of the individual particle beams upon incidence on the object 7 with disturbance and the interaction cross section of the individual particle beams upon incidence on the object 7 without disturbance or with respect to the nominal interaction cross section.

In addition to mechanical and/or acoustic disruptions, the disturbing influence can also be magnetic disturbing influences. Magnetic disturbing influences can manifest for example in a distorted or for example ellipsoidal beam diameter and/or interaction cross section of the individual particle beams 3 upon incidence on the object 7. For example, it is possible for the ellipticity of the found latent structures 51 to be determined and for them to be used as a measure of the magnetic disturbing influence.

In a further method step (not illustrated), it is possible for example to compensate for the disturbing influences found or to readjust for example the multi-beam particle microscope 1 based on the analysis of the latent structures. In this way it is possible, for example, to correct an astigmatism caused by disturbing influences by way of the readjustment.

Alternatively or additionally it is possible to incorporate in the described workflow a method step in which a disturbing influence is selectively switched on or off. For example, it is possible to produce magnetic fields via Helmholtz coils, the selective switching on and off of pumps for reasons of vibrations or acoustic disturbing influences is also possible. By analysis of measurement series with known disturbing influences and measurement series without those disturbing influences, with otherwise identical framework parameters or ambient parameters, the magnitude of the disturbing influence can be better quantified.

In the workflow of a method according to the disclosure according to FIG. 2, which has been described by way of example, the stationary scan at a position and the raster scan at the same position take place in direct succession. However, it is also possible that, at various positions, initially a stationary scan or irradiation for producing latent structures 51 takes place and the raster scan of the sample 7 takes place only afterward, possibly after a temporary removal of the object 7. For this purpose, the latency times of the latent structures 51 is correspondingly long, for correspondingly selected objects 7, they can be in the range of several hours, so that the alternative possibility of the sequence exists in general. However, the workflow according to FIG. 2 is optional, because homing in on the corresponding positions is performed only once, which saves time and, in addition, reduces losses in accuracy, because, after the stationary scan, the individual particle beams 3 will be exactly at the position around which they are also intended to perform the raster scan.

Further modifications of the method described will be apparent to a person skilled in the art without an inventive step being involved.

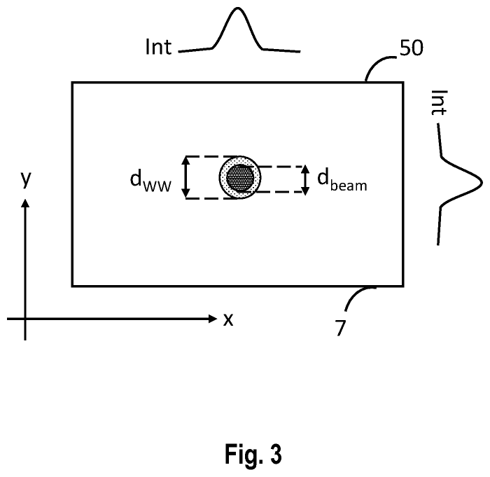

FIG. 3 schematically illustrates the widening of an interaction zone. FIG. 3 shows a beam diameter of an individual particle beam 3 in a single field of view 50. The individual particle beam 3 here has an undisturbed beam diameter d_{beam}. The intensity profile of the individual particle beam 3 is shown by the additional curves with the designation Int. The intensity profile is identical in the x-direction and in the y-direction, and the geometry of the illumination spot is ideally circular. Due to the incidence of the individual particle beams on the object 7, interaction processes of the individual charged particle beams 3 with the object 7 occur: Here, for example secondary particles in the form of second electron beams are released from the object 7. The secondary particles are released here not only exactly in the z-direction (perpendicular to the plane of the sheet of FIG. 3) but also slightly obliquely. In addition, these processes within the sample also occur in a cascade-type manner. The interaction volume of the object 7 results in the emergence of secondary particles from a surface having a greater area than the illumination spot. Consequently, the interaction cross section of an individual particle beam 3 with the sample 7 is slightly larger than the beam diameter of the incident individual particle beam 3. FIG. 3 shows the interaction cross section as an outer circle, for the diameter d_{ww} of which: d_{ww}>d_{beam}. According to an embodiment of the disclosure, the analysis of the latent structures 51 comprises determining deflections of the individual particle beams 3 from an equilibrium position. The equilibrium position can relate here to a situation without a disturbing influence. A latent structure 51 that then occurs can be, for example, point-shaped or circular. Deflections of the individual particle beams 3 can be determined on the basis of a nominal or undisturbed beam diameter d_{beam} of the individual particle beams 3 and/or on the basis of a nominal or undisturbed interaction cross section d_{ww} of the individual particle beams 3 upon incidence on the object 7.

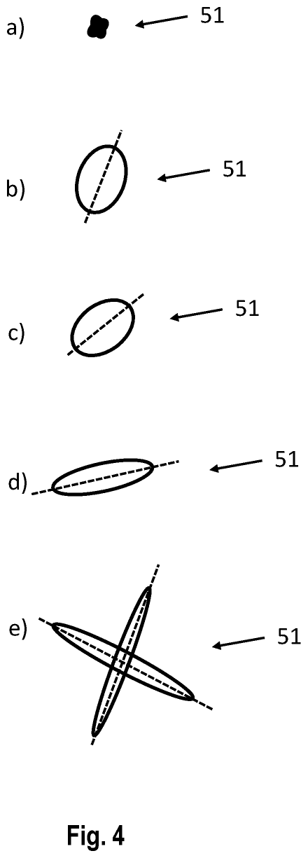

FIG. 4 schematically shows different geometries of latent structures 51 on an object. In the example shown, the latent structures 51 are formed in each case in the presence of a disturbing influence; a latent structure without the presence of a disturbing influence (not illustrated) could be, for example, point-shaped or circular. FIG. 4a shows a small, irregular latent structure 51. FIGS. 4b, 4c and 4d each show an ellipsoidal latent structure 51, wherein the ellipticity varies in the illustrations. In addition, the direction of the major axis of the respective ellipse, indicated by the dashed lines, also varies; FIG. 4e shows by way of example a latent structure 51 with the approximate shape of a cross, which can also be imagined as an overlay of two ellipsoidal structures. Here, the latent structures 51 illustrated in FIG. 4 should merely be understood to be possible examples; greater or smaller, more regular or more irregular structures of any type can be produced as the latent structures 51, which depends firstly on the type of the disturbing influence and secondly on the type of the sample 7 used.

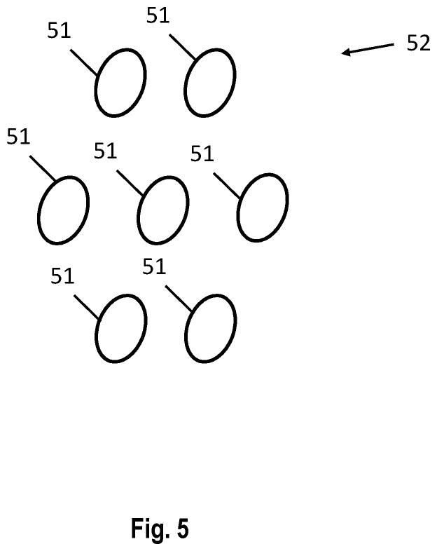

FIG. 5 schematically shows latent structures of individual particle beams 3 in a raster arrangement or an array 52. In the example shown, a raster arrangement of the multi-beam particle microscope 1 comprises a total of seven individual particle beams 3, which are arranged hexagonally with respect to one another. Each individual particle beam 3 now has produced a latent structure 51 in a predefined position by way of stationary irradiation, which latent structure has then been raster-scanned. This result is shown in FIG. 5. The latent structures 51 obtained are substantially identical in the example shown for each of the individual particle beams 3. They are in each case ellipses, for which the ellipticity and alignment of the major semiaxes of the ellipses in each case substantially correspond. A disturbing influence has in this case for example exerted a homogeneous influence on the individual particle beams 3. The type of latent structures 51 shown in FIG. 5 can occur, for example, in the case of time-dependent external disturbing influences, such as in the case of alternating magnetic fields, which correspondingly influence the respective individual particle beam 3 during the stationary irradiation or guide it over the object 7. In another example (see FIG. 4a), the latent structures 51 can be star-shaped latent structures 51, which can arise for example due to static magnetic fields that are present—these star-shaped structures can occur if illumination spots which are not ideally point-shaped or not ideally circular migrate over the object 7. These star-shaped structures are then (also) based on an astigmatism, which can be compensated for, for example, by a corresponding readjustment of the individual particle beams 3.

According to an alternative example (not illustrated), the latent structures per individual particle beam could also have different designs. As part of the analysis of the performance of the multi-beam particle microscope 1, it is also feasible to compare the latent structures 51 for each individual particle beam with one another in order to find out whether the disturbing influences on each of the individual particle beams have the same magnitude or different magnitudes.

In addition, further possible applications arise on the basis of the formation of the latent structures 51 as discovered by the inventors, such as for example the use of the latent structures 51 as marker structures on an object 7. For example, it is possible to implement a method for producing marker structures on an object 7, in particular on a semiconductor sample, which includes the following step: irradiating the object in a stationary manner with the plurality of individual particle beams 3 during a predetermined irradiation time T, as a result of which latent structures 51 are formed in the form of marker structures on the object 7. These marker structures can significantly simplify alignment or registration processes for example during the analysis of semiconductor wafers.

### LIST OF REFERENCE SIGNS

1 Multi-beam particle microscope
3 Primary particle beams (individual particle beams)
5 Beam spots, incidence locations
7 Object
9 Secondary particle beams
10 Computer system, controller
11 Secondary particle beam path
13 Primary particle beam path
25 Sample surface, wafer surface
50 Single field of view (individual beam system)
51 Latent structure
52 Array of latent structures
100 Objective lens system
101 Object plane
102 Objective lens
103 Field
200 Detector system
205 Projection lens
209 Particle multi-detector
211 Detection plane
213 Incidence locations
215 Detection region
217 Field
300 Beam generating apparatus
301 Particle source
303 Collimation lens system
305 Multi-aperture arrangement
306 Micro-optics
307 Field lens
309 Diverging particle beam
311 Illuminating particle beam
313 Multi-aperture plate
315 Openings in the multi-aperture plate
317 Midpoints of the openings
319 Field
323 Beam foci
325 Intermediate image plane
S0 Providing object
S1 Homing in on position 1
S2 Stationary scan position 1
S3 Raster scan position 1
S4 Homing in on position 2
S5 Stationary scan position 2
S6 Raster scan position 2
S7 Position n
S8 Analyzing latent structures
S9 Quantifying disturbing influence

What is claimed is:

1. A method of using a multi-beam particle microscope which generates a plurality of individual charged particle beams arranged in a raster arrangement, the method comprising:
stationary scanning an object at a first position via the plurality of the individual particle beams during a predetermined irradiation time T, thereby forming latent structures on the object;
raster-scanning the first position of the object comprising the latent structures via the plurality of the individual particle beams; and
analyzing the latent structures.

2. The method of claim 1, wherein for a dose Dₛₜₐₜ during the stationary scanning of the object in the first position and for a dose Dᵣₐₛₜ during the raster scanning of the object comprising the first position, 1,000 Dᵣₐₛₜ≤Dₛₜₐₜ≤100,000 Dᵣₐₛₜ.

3. The method as claimed of claim 1, wherein, for the irradiation time T in the first position, 0.1 s≤T≤5 s.

4. The method of claim 1, further comprising setting a pause time between stationary scanning the object in the first position and raster scanning the object.

5. The method of claim 1, wherein analyzing the latent structures comprises determining deflections of the individual particle beams from an equilibrium position.

6. The method of claim 5, wherein the deflections are determined based on:
a nominal or undisturbed beam diameter of the individual particle beams; and/or
a nominal or undisturbed interaction cross section of the individual particle beams upon incidence on the object.

7. The method of claim 1, further comprising switching a disturbing influence on and/or switching a disturbing influence off.

8. The method of claim 1, further comprising quantifying a disturbing influence based on the analysis of the latent structures.

9. The method of claim 1, wherein:
the multi-beam particle microscope comprises a collective scan deflector configured to collectively move the raster arrangement of the plurality of individual particle beams over an object surface in a raster-type manner;
raster-scanning the object comprises controlling the collective scan deflector; and
stationary scanning the object comprises stopping or switching off the collective scan deflector.

10. The method of claim 9, wherein:
the multi-beam particle microscope has a collective beam blanker configured to collectively deflect the plurality of individual particle beams so that they are not incident on the object; and
stationary scanning the object comprises releasing the collective beam blanker when the collective beam blanker is stopped or switched-off collective scan deflector so that the plurality of the individual particle beams are incident on the object.

11. The method of claim 1, wherein a full single field of view or only a partial region of a single field of view is raster-scanned by each individual particle beam during raster scanning the object comprising the first position.

12. The method of claim 11, further comprising setting a size of a region of a single field of view that is to be raster-scanned based on a magnitude of a disturbing influence and/or of properties of the object.

13. The method of claim 1, wherein stationary scanning takes place centrally in a single field of view and/or in an equilibrium position of the individual particle beams in the raster arrangement.

14. The method of claim 1, further comprising compensating the disturbing influences.

15. The method of claim 1, wherein the disturbing influences comprise mechanical influences, acoustic influences and/or magnetic influences.

16. The method of claim 1, further comprising adjusting the multi-beam particle microscope based on the analysis of the latent structures.

17. The method of claim 1, wherein a latency time of the latent structures is more than 10 minutes.

18. The method of claim 1, wherein the latent structures are produced by stationary charges on the object.

19. The method of claim 1, wherein the latent structures are produced by topographical effects based on structural changes on the sample.

20. The method of claim 1, wherein the latent structures are produced by chemical changes on the sample.

21. The method of claim 1, wherein the latent structures are produced by energetic excitations.

22. The method of claim 1, wherein the latent structures are produced exclusively by irradiating the object with the plurality of individual particle beams and without supplying process gas.

23. The method of claim 1, further comprising:
stationary scanning the object at a second position via the plurality of the individual particle beams during the predetermined irradiation time T, thereby forming latent structures on the object; and
raster-scanning the object comprising the second position with the latent structures via the plurality of the individual particle beams.

24. One or more machine-readable hardware storage devices comprising instructions that are executable by one or more processing devices to perform operations comprising the method of claim 1.

25. A system comprising:
one or more processing devices; and
one or more machine-readable hardware storage devices comprising instructions that are executable by the one or more processing devices to perform operations comprising the method of claim 1.

26. The system of claim 25, wherein the multi-beam particle microscope comprises:
a multi-beam generator configured to generate a first field of a plurality of charged first particle beams;
da first particle optical unit with a first particle-optical beam path, the first particle optical unit configured to image the generated individual particle beams onto a sample surface in the object plane such that the first particle beams are incident on the sample surface at incidence locations which form a second field;
a detection system comprising a multiplicity of detection regions that form a third field;
a second particle optical unit with a second particle-optical beam path, the second particle optical unit configured to image second individual particle beams, which emanate from the incidence locations in the second field, onto the third field of the detection regions of the detection system;
a magnetic and/or electrostatic objective lens, through which both the first and the second individual particle beams pass;
a beam switch in the first particle-optical beam path between the multi-beam generator and the objective lens, the beam switch in the second particle-optical beam path between the objective lens and the detection system;
a collective scan deflector between the beam switch and the sample surface, the collective scan deflector and configured to collectively raster-scan the sample surface using the plurality of charged first particle beams;
a mode-selection device configured to select an analysis operating mode in which latent structures are producible on a sample; and
a controller,
wherein the controller is configured to control the collective scan deflector in the analysis operating mode:
so that a stationary scan of the object at a predefined position takes place via the plurality of the individual particle beams during a predetermined irradiation time, thereby forming latent structures on the object; and
after the stationary scan so that a raster scan of the object comprising the predefined position with the formed latent structures takes place via the plurality of the individual particle beams.

27. The system of claim 26, wherein, for a dose Dₛₜₐₜ during the stationary scan of the object in the first position and for a dose Dᵣₐₛₜ during the raster scan of the object comprising the first position, 1,000 Dᵣₐₛₜ≤Dₛₜₐₜ≤100,000 Dᵣₐₛₜ.

28. The system of claim 27, further comprising a collective beam blanker configured to deflect the plurality of the first individual particle beams so that the first individual particle beams are not incident on the sample, wherein the controller is configured to control the collective beam blanker in the analysis operating mode so that a stationary scan of the object at the predefined position takes place via the plurality of the individual particle beams during the predetermined irradiation time T with a released beam blanker.

29. A method of producing marker structures on an object via a multi-beam particle beam system operating with a plurality of individual charged particle beams, the method comprising:
irradiating the object in a stationary manner with the plurality of individual particle beams during a predetermined irradiation time, thereby forming latent structures in the form of the marker structures on the object.
